(19) United States
(12) Patent Application Publication
(10) Pub. No.: US 2007/0267946 A1
(43) Pub. Date: Nov. 22, 2007

(54) Device for converting mechanical energy into electrical energy

(75) Inventors: Thomas Haas, Regensburg (DE); Franz Hillenmayer, Burglengenfeld (DE)

Correspondence Address: LERNER GREENBERG STEMER LLP, P O BOX 2480, HOLLYWOOD, FL, 33022-2480, US

(73) Assignee: Siemens Aktiengesellschaft

(21) Appl. No.: 11/805,150

(22) Filed: May 22, 2007

(30) Foreign Application Priority Data
May 22, 2006 (DE) 10 2006 024 006.5

(51) Int. Cl. H01L 41/00

(52) U.S. Cl. 310/339

(57) ABSTRACT

A device for converting mechanical energy into useful electrical energy has a first component, a second component that is mechanically linked to the first component, and a mechanical-electrical energy converter. The second component is linked to the first component by way of a movement-damping device in such a way that when it is moving, with a direction of motion, the second component moves relative to the first component and the mechanical-electrical energy converter is mechanically decoupled from the applied forces on the first component and on the second component. The device is particularly suitable for tire pressure monitoring systems for vehicles

### CROSS-REFERENCE TO RELATED APPLICATION

This application claims the priority, under 35 U.S.C. § 119, of German application DE 10 2006 024 006.5, filed May 22, 2006; the prior application is herewith incorporated by reference in its entirety.

### BACKGROUND OF THE INVENTION

### FIELD OF THE INVENTION

The invention relates to a device for converting mechanical energy into useful electrical energy. The device has a first component and a second component which is linked mechanically to the first component and a mechanical-electrical energy converter which is linked to the second component.

In the automotive industry, items of physical data, such as for example the tire pressure, are measured by way of measuring units which are built onto the wheel. These items of data are used for monitoring the setpoint conditions in the tire. The energy required by the sensors for monitoring the physical variables, and for transmitting measured values, for example by radio, is typically made available by a battery in the measuring unit. However, the service life of batteries is very heavily dependent on the temperature and the frequency of the transmission intervals. Thus the service life of the measuring unit is primarily dependent on the service life of the battery.

There are also known possibilities for the transport of energy from the vehicle into the tire, such as inductive energy transport. It is also possible to effect the generation of energy in the tire/wheel.

U.S. Pat. No. 4,510,484 (German published patent application DE 3407254 A1) describes a bending reed for energy conversion, which is aligned along the length of a radial line out from the center of the wheel, i.e. in a centrifugal direction. As a result of vibrations/dynamic force changes, this bending element is deformed, with a consequent material-dependent conversion into electrical energy. A mass attached to the free-floating end amplifies the displacement. A disadvantageous consequence of this is that there is a heavy pre-stressing/loading of the bending element if the attached mass is subject to an acceleration.

A tire pressure measurement system with an energy generator is known from U.S. Pat. No. 5,889,464 (European published patent application EP 1 043 577 A1). A piezo-element which is mounted on a spring converts mechanical deformations into electrical energy. On one side, the spring has a fixed attachment, on the other side it is free to oscillate, with the oscillation being amplified by an additionally attached mass. Here again, a disadvantage is the pre-stressing of the bending beam, which is produced by the affixed mass and an acceleration. This can lead to the bending beam being damaged.

An energy generator, disposed in a vehicle tire and based on the piezo-effect, is again known from Japanese patent application JP 2004 032 929 A. The bending elements are arranged perpendicularly to the axis of rotation, requiring an accelerated rotation of the tire, which leads to a displacement of the piezo-element and is ultimately converted into electrical energy.

Nor, with the known approaches to energy generation in a tire/wheel, is any distinction made between structural interface joints and energy conversion elements/systems. For example, the piezo-element as an energy conversion element/system is joined directly to the structural interface joint between a fixed and a relatively movable component, e.g. a bending reed.

In the case of energy conversion in a wheel/tire, one attempts to convert sufficient mechanical energy into usable electrical energy to supply an existing electronic component with energy. Mechanical energy is defined as follows:

| | | |
|---|---|---|
| $\begin{matrix}{E}_{Mechanical} = {\int }_{1}^{2} F ( x ) * d x \\ = {\int }_{1}^{2} m * a ( x ) * d x\end{matrix}$ | E_{MechanicalF(x):dx:m:a(x):} | Mechanical energyForceDeformation by F(x)MassAcceleration |

The parameters which affect the generation of mechanical energy are:
Force F(x) (force can be realized by increasing the mass m or/and by an acceleration a(x));
Deformation dx due to a change in the force (influence of the spring/damping constants)

The objective of the mechanical concept should be to obtain sufficient mechanical energy, which by various approaches is to be converted to electrical energy.

### BRIEF SUMMARY OF THE INVENTION

It is accordingly an object of the invention to provide a device for converting mechanical energy into useful electrical energy which overcomes the above-mentioned disadvantages of the heretofore-known devices and methods of this general type and which provides for improved yield in the conversion of mechanical to electrical energy.

With the foregoing and other objects in view there is provided, in accordance with the invention, a device for converting mechanical energy into useful electrical energy, comprising:

a first component and a second component;

a mechanical-electrical energy converter connected to the first component or the second component; and

a movement-damping device mechanically linking said second component to said first component such that, upon movement in a direction of motion, said second component moves relative to said first component and said mechanical-electrical energy converter is subject to a load substantially exclusively from a force resulting from the weight and the acceleration of the energy converter.

In other words, the objects of the invention are achieved with a device for converting mechanical energy into useful electrical energy that includes a first component and a second component which is linked mechanically to the first component and a mechanical-electrical energy converter. The second component is linked to the first component by means of a movement-damping device in such a way that when it is moving, with a direction of motion, the second component moves relative to the first component and the mechanical-electrical energy converter is mechanically decoupled from the forces to which the first component and the second component are subject.

For the structural embodiment, the basic principle for the generation of mechanical energy is a relative movement between a fixed component and a relatively movable component, so that a mechanical-electrical energy converter can be decoupled. This allows the optimization of the relative movement and the optimization of the energy conversion to be considered separately.

In a preferred form of embodiment of the invention, the movement damping device includes at least one element, such as for example a leaf spring, a helical spring, a wire, a ball bearing or the like, which defines the arm of a pendulum or path of a curve, or realizes a relative movement between the first component and the second component.

In a preferred embodiment of the invention, the movement damping device includes at least one element which defines the path of a curve, or realizes a relative movement between the first component and the second component.

In a preferred embodiment of the invention, the mechanical-electrical energy converter includes a piezo-ceramic material.

In a further preferred embodiment of the invention, the mechanical-electrical energy converter includes an inductive converter or a capacitive converter.

In a further preferred embodiment of the invention, an additional mass is affixed to the mechanical-electrical energy converter.

With these types of energy conversion, one always requires a relative movement of two components and/or a deformation of a material, for example by a force and/or a change in acceleration.

In a further preferred embodiment of the invention, the first component or the second component each takes the form of a circuit board, a housing, an antenna or another component deployed in a measuring device which is already being used.

Other features which are considered as characteristic for the invention are set forth in the appended claims.

Although the invention is illustrated and described herein as embodied in device for converting mechanical energy into electrical energy, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a perspective view of a device for energy conversion;

FIG. 2 is a sectional view of a decoupling device for lateral movements where the displacement is small;

FIG. 3 is a sectional view of a decoupling device for lateral and vertical movements where the displacement is small;

FIG. 4 is a sectional view of a decoupling device with a wire link;

FIG. 5 is a sectional view of a decoupling device with bearings, for lateral movements where the displacement is small; and

FIG. 6 is a sectional view of a device with a deformable circuit board.

### DETAILED DESCRIPTION OF THE INVENTION

In the following description of a preferred form of embodiment of the present invention, the same reference marks are used for components which are the same or similar, and which are functionally equivalent.

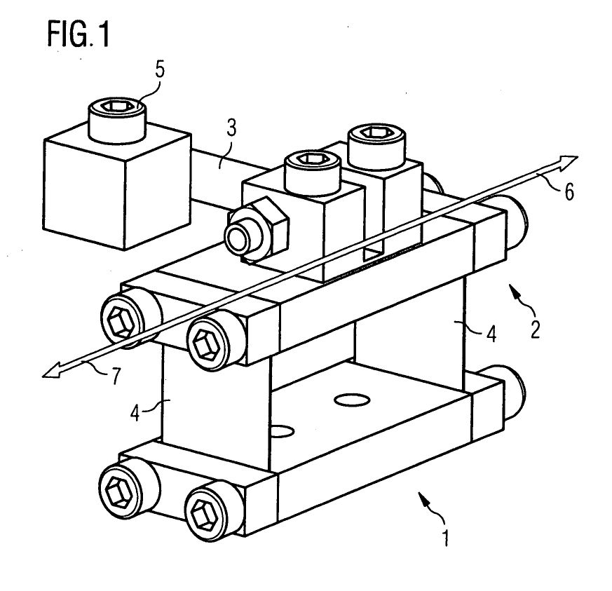

Referring now to the figures of the drawing in detail and first, particularly, to FIG. 1 thereof, there is shown a device for energy conversion such as is arranged for example in a tire pressure measurement system on a vehicle. The device comprises a rigidly mounted component 1, a movable component 2 and a mechanical-electrical energy converter 3. The rigidly mounted component 1 and the movable component 2 are linked by a movement-damping device 4. Typically, the device moves in the indicated direction 6, 7. The movement-damping device 4 consists, for example, of two leaf springs, with each of their ends clamped between the rigidly mounted component 1 and the movable component 2. The mechanical-electrical energy converter 3 can take the form of a piezo-ceramic, capacitive or inductive energy converter. Here, the piezo-ceramic energy converter 3 can be realized in various forms such as, for example, a purely ceramic beam, a bimorph-beam and/or a metal/ceramic-bimorph-beam, wherein the relative movement is manifest as a deformation. Also attached to the mechanical-electrical energy converter is a mass 5, which ensures pre-stressing of the mechanical-electrical energy converter 3 and can be rigidly linked to the rigidly mounted first component 1, 5. Furthermore, it would be possible to use a capacitive and/or inductive mechanical-electrical energy converter 3. The relative movement would induce a charge displacement between the plates in the case of a capacitive converter, and a change in the magnetic flux density in the case of an inductive converter.

For energy conversion the most important characteristic is the electrical attenuation of the energy conversion material/joint or the energy conversion system. However, in order to generate the best possible relative movement, and thus a high mechanical energy, this being realized by the structural interface joint, the complete system must be laid out with an oscillatory capability. In this, the spring stiffness/oscillatory capability has an enormous influence. Decoupling enables the parameters of the spring stiffness/oscillatory capability and the damping of the total system to be optimized/arranged independently of each other. This leads to an optimal spring stiffness/oscillatory capability of the structural interface joint, and an optimal relative movement and an optimal damping of the mechanical-electrical energy converter is achieved for the extraction of energy with a relatively small cross influence.

In addition, the decoupling means that the energy conversion system is loaded as little as possible, because the complete oscillatable mass, and hence the total force, is absorbed by the structural interface joint. The energy conversion system is only loaded by the force which results from its own weight and acceleration.

In a further preferred form of embodiment of the invention, the first component 1, the second component 2 or the additional mass 5 each takes the form of a circuit board, a housing, an antenna or another component which is already present in an existing measuring device.

Here, the components should continue to carry out their previous functions, and should have in addition multiple functions. For example, the “oscillatable” mass can be realized by a circuit board, on which are arranged the components of the measuring unit. In addition, the bending beam could as its supplementary function be the link between the housing and the circuit board, and improve the damping. Another example could be that the fixed clamping for the bending beam has the function of a “housing”, and thus protects against external influences.

Advantages of using an integrated generator system:
no additional mass with the ability to oscillate is required;
weight reduction of the measuring unit in the wheel/tire (lower unsprung weight);
more compact construction; and
additional mechanical load reduction on some components of the measuring unit (such as for example: lower risk of damage to the HW components).

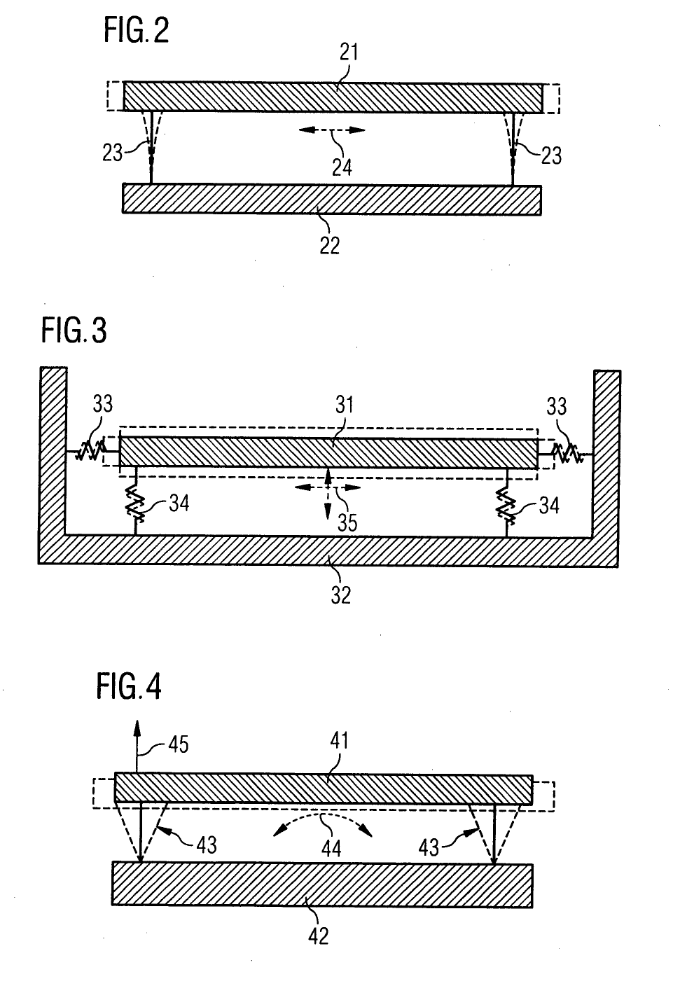

FIG. 2 shows a decoupling device for lateral movements when the displacement is small. A rigidly mounted component 22 is linked to a movable component 21 via a movement damping device 23, e.g. leaf springs. As a consequence the movable component 21 makes a lateral movement 24 with a small displacement relative to the rigidly mounted component 22.

FIG. 3 shows a decoupling device for lateral and vertical movements when the displacement is small. A rigidly mounted component 32 is linked to a movable component 31 via movement damping devices 33, 34, e.g. helical springs. As a consequence the movable component 31 makes lateral and vertical movements 35 with a small displacement relative to the rigidly mounted component 32. Consideration can also be given to deformable plastic elements for the movement damping devices 33, 34.

FIG. 4 shows a decoupling device with a wire link. Here, a movable component 41 is linked to a fixed component 42 via a wire 43. In operation, the movable component 41 is pre-stressed in a vertical direction 45, so that during a movement the wire 43 functions in addition as a fixing in terms of the displacement. The movable component 41 thus makes a movement 44 relative to the rigidly mounted component 42, without the disadvantageous influence of a spring stiffness in component 43, which damps the oscillation.

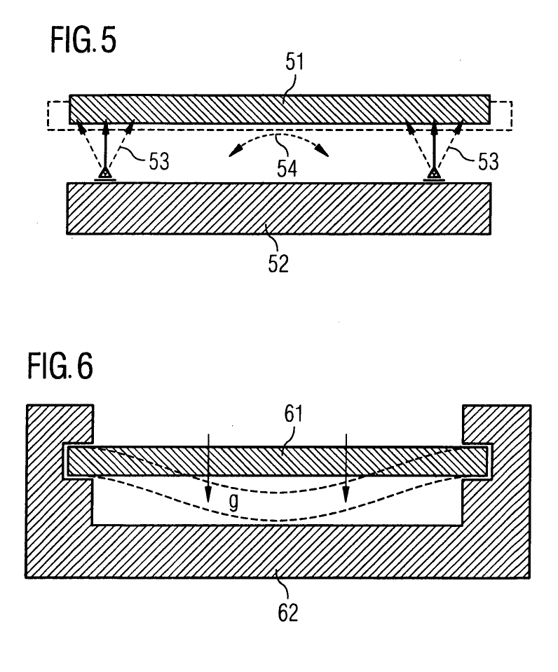

FIG. 5 shows a decoupling device for lateral movements, with bearings. A rigidly mounted component 52 is linked to a movable component 51 via a movement-damping device 53, e.g. a floating bearing/restrained bearing combination. As a consequence the movable component 51 makes a lateral movement 54 with a small displacement relative to the rigidly mounted component 52.

FIG. 6 shows a device with a deformable circuit board. It shows a circuit board 61 in its undisplaced state (i.e., its position of repose) and in the displaced deformed state. The deformable circuit board 61 is fixed on both sides at opposite end regions.

The invention and the forms of embodiment described lead to the following advantages compared to the prior art, especially in comparison with battery powered measuring systems:
no service life reductions due to the influence of temperature
increased service life
no additional oscillatable mass is required
reduction in weight of the measuring unit in the wheel/tire (lower unsprung weight)
more compact construction
additional mechanical load reduction on some components of the measuring unit (such as for example lower risk of damage to the hardware components)
can be used for other products such as for example access control systems for vehicles.

The present invention is particularly suitable for a tire pressure monitoring system for vehicles.

1. A device for converting mechanical energy into useful electrical energy, comprising:
a first component;
a second component;
a mechanical-electrical energy converter;
a movement-damping device mechanically linking said second component to said first component such that, upon movement in a direction of motion, said second component moves relative to said first component and said mechanical-electrical energy converter is only subject to a load from a force resulting from a weight and an acceleration thereof.

2. The device according to claim 1, wherein said movement damping device incorporates at least one element representing an arm of a pendulum.

3. The device according to claim 1, wherein said mechanical-electrical energy converter comprises a piezo-ceramic material.

4. The device according to claim 1, wherein said mechanical-electrical energy converter comprises an inductive converter.

5. The device according to claim 1, wherein said mechanical-electrical energy converter comprises a capacitive converter.

6. The device according to claim 1, which further comprises an additional mass attached to said mechanical-electrical energy converter, and said mass being connectible to said first component.

7. The device according to claim 1, wherein at least one of said first component, said second component, or said additional mass is a circuit board, a housing, an antenna, or another component already deployed in an existing measuring device.
